(19) United States
(12) Patent Application Publication
(10) Pub. No.: US 2021/0358857 A1
(43) Pub. Date: Nov. 18, 2021

(54) DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Linfeng LIU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/625,782

(22) PCT Filed: Dec. 10, 2019
(86) PCT No.: PCT/CN2019/124411

§ 371 Date: Dec. 23, 2019

(30) Foreign Application Priority Data
Dec. 2, 2019 (CN) 201911213770.3

(51) Int. Cl. H01L 23/544; G02F 1/1362; G02F 1/1368; G02F 1/1343; H01L 27/12

(52) U.S. Cl. CPC H01L 23/544; G02F 1/136286; G02F 1/1368; H01L 2223/54406; G02F 1/136209; H01L 27/124; G02F 1/134309

(57) ABSTRACT

The present invention provides a display panel and a display device. The display panel includes a first substrate, a second substrate, and multiple process markings. The first substrate includes multiple scan lines and multiple data lines. The scan lines and the data lines are intersected with each other to form multiple grids. The second substrate is arranged corresponding to the first substrate. The process markings are arranged on an inner surface of the first substrate. Projections of the process markings projected on the first substrate are located within projections of the grids projected on the first substrate.

### 1. FIELD OF DISCLOSURE

The present disclosure relates to a field of display technology and in particular, to a display panel and a display device.

### 2. DESCRIPTION OF RELATED ART

In a manufacturing process of a liquid crystal display, in order to automate the production of the production line, it is determined that the information of each substrate is supplied, and each substrate has a unique corresponding process marking. For example, the glass substrate has a glass identification code and a chip has a chip identification code. The process markings in conventional techniques are generally provided in a bezel area of a display panel.

However, with development and improvement of display devices, display devices with higher screen ratios have become mainstream. For a display panel with an ultra-narrow bezel, it is difficult to set an easily identifiable process marking in the bezel area.

### SUMMARY

The present invention provides a display panel and a display device to solve a problem that it is difficult to arrange easily identifiable process markings in a bezel area of a display panel with an ultra-narrow bezel.

The present invention provides a display panel, comprising:

a first substrate comprising a plurality of scan lines and a plurality of data lines, wherein the scan lines and the data lines are intersected with each other to form a plurality of grids;

a second substrate disposed corresponding to the first substrate; and

a plurality of process markings arranged on an inner surface of the first substrate, wherein projections of the process markings projected on the first substrate are located within projections of the grids projected on the first substrate.

In the display panel of the present invention, the process markings are arranged in a same layer as the scan lines or the data lines.

In the display panel of the present invention, the process markings comprise a plurality of numbers and/or letters, and the adjacent numbers and/or letters are separated by at least one of the grids.

In the display panel of the present invention, the process marking comprises a first pattern and a second pattern surrounding a periphery of the first pattern; and the first pattern and the second pattern are made of a same material as a material of the scan lines or the data lines.

In the display panel of the present invention, the second pattern comprises a plurality of gaps spaced apart from each other.

In the display panel of the present invention, the process markings comprise a first process marking and a second process marking, the first process marking is arranged in a same layer as the data lines, the second process marking is arranged in a same layer as the scan lines, and a projection of the first process marking projected on the first substrate is non-overlapped with a projection of the second process marking projected on the first substrate.

In the display panel of the present invention, the first process marking is made of a same material as a material of the data lines, and the second process marking is made of a same material as a material of the scan lines.

In the display panel of the present invention, the first substrate further comprises a thin film transistor, the thin film transistor comprises a gate, a source, and a drain; and

the projection of the process markings projected on the first substrate are non-overlapped with projections of the gate, the source, and the drain projected on the first substrate.

In the display panel of the present invention, the first substrate further comprises a pixel electrode, and the process markings are arranged in a same layer as the pixel electrode.

In the display panel of the present invention, the second substrate further comprises a black matrix, and the process markings are arranged in a same layer as the black matrix.

The present invention further provides a display device comprising a display panel, the display panel comprising:

a first substrate comprising a plurality of scan lines and a plurality of data lines, wherein the scan lines and the data lines are intersected with each other to form a plurality of grids;

a second substrate disposed corresponding to the first substrate; and

a plurality of process markings arranged on an inner surface of the first substrate, wherein projections of the process markings projected on the first substrate are located within projections of the grids projected on the first substrate.

In the display device of the present invention, the process markings are arranged in a same layer as the scan lines or the data lines.

In the display device of the present invention, the process markings comprise a plurality of numbers and/or letters, and the adjacent numbers and/or letters are separated by at least one of the grids.

In the display device of the present invention, the process marking comprises a first pattern and a second pattern surrounding a periphery of the first pattern; and the first pattern and the second pattern are made of a same material as a material of the scan lines or the data lines.

In the display device of the present invention, the second pattern comprises a plurality of gaps spaced apart from each other.

In the display device of the present invention, the process markings comprise a first process marking and a second process marking, the first process marking is arranged in a same layer as the data lines, the second process marking is arranged in a same layer as the scan lines, and a projection of the first process marking projected on the first substrate is non-overlapped with a projection of the second process marking projected on the first substrate.

In the display panel of the present invention, the first process marking is made of a same material as a material of the data lines, and the second process marking is made of a same material as a material of the scan lines.

In the display device of the present invention, the first substrate further comprises a thin film transistor, the thin film transistor comprises a gate, a source, and a drain; and

the projection of the process markings projected on the first substrate are non-overlapped with projections of the gate, the source, and the drain projected on the first substrate.

In the display device of the present invention, the first substrate further comprises a pixel electrode, and the process markings are arranged in a same layer as the pixel electrode.

In the display device of the present invention, the second substrate further comprises a black matrix, and the process markings are arranged in a same layer as the black matrix.

The present application provides process markings arranged in grids, formed by scan lines and data lines intersected with each other, on an inner surface of a first substrate to solve a technical problem that it is difficult to arrange process markings in a bezel area of a display panel with an ultra-narrow bezel, and to facilitate recognition of the process markings.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work.

FIG. 1 is a first schematic planar view illustrating a display panel according to one embodiment of the present invention;

FIG. 2 is a first schematic structural view illustrating the display panel according to one embodiment of the present invention;

FIG. 3 is a second schematic structural view illustrating the display panel according to one embodiment of the present invention;

FIG. 4 is a second schematic planar view illustrating the display panel according to one embodiment of the present invention;

FIG. 5 is a third schematic planar view illustrating the display panel according to one embodiment of the present invention;

FIG. 6 is a fourth schematic planar view illustrating the display panel according to one embodiment of the present invention;

FIG. 7 is a third schematic structural view illustrating the display panel according to one embodiment of the present invention;

FIG. 8 is a fourth schematic structural view illustrating the display panel according to one embodiment of the present invention; and

FIG. 9 is a fifth schematic structural view illustrating the display panel according to the one embodiment of the present invention.

### DETAILED DESCRIPTION OF EMBODIMENTS

The embodiments of the present invention will be clearly and completely described below with reference to the accompanying drawings. It is apparent that the embodiments are only some embodiments of the present invention, and not all of the embodiments. All other embodiments obtained by those skilled in the art based on the embodiments of the present invention without an inventive step are deemed to be within the protection scope of the present invention.

In the present disclosure, it should be understood that terms such as “first” and “second” are used for illustrative purposes and not intended to indicate or imply relative importance or significance or impliedly indicate quantity of the technical feature referred to. Thus, the feature defined with “first” and “second” may indicate inclusion of one or more this feature, so the present invention is not limited in this regard.

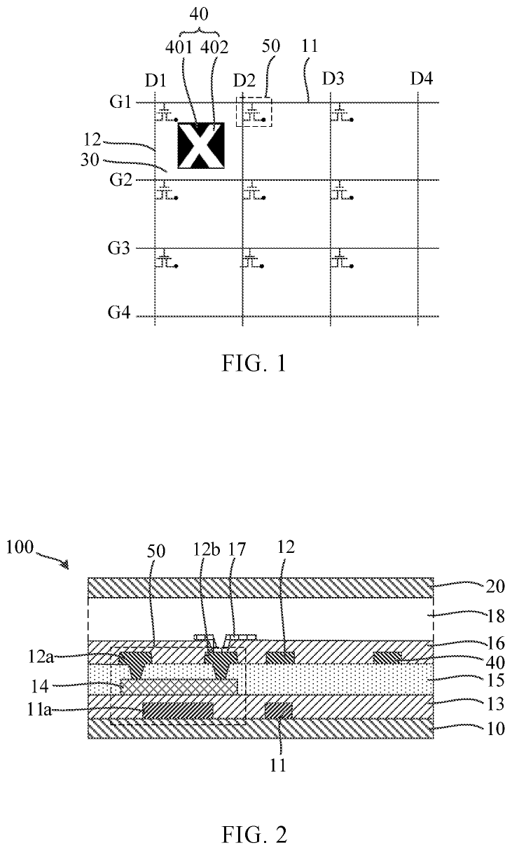

Please refer to FIGS. 1 and 2. FIG. 1 is a first schematic planar view illustrating a display panel 100 according to one embodiment of the present invention, and FIG. 2 is a first structural schematic view illustrating the display panel 100 according to one embodiment of the present invention. The display panel 100 comprises a first substrate 10, a second substrate 20, and a plurality of process markings 40 arranged on an inner surface of the first substrate 10. The first substrate 10 comprises a plurality of scan lines 11 and a plurality of data lines 12. The scan lines 11 and the data lines 12 are intersected with each other to form a plurality of grids 30. Projections of the process markings 40 projected on the first substrate 10 are located within projections of the grids 30 projected on the first substrate 10.

According to one embodiment of the present invention, the process markings 40 of the present embodiment are arranged on the inner surface of the first substrate 10, and the projections of the process markings 40 projected on the first substrate 10 are located within the projections of the grids 30, formed by the scan lines 11 and the data lines 12 intersected with each other, on the first substrate 10. The process markings 40 can be arranged in a display region of the display panel 100, thus avoiding arrangement of the process markings 40 in a bezel area of the display panel 100 with an ultra-narrow bezel, thereby avoiding a technical problem that the process markings 40 are difficult to identify, and facilitating recognition of the process markings 40.

Please refer to FIGS. 1 and 2. The first substrate 10 and the second substrate 20 can be glass substrates, quartz substrates, resin substrates, flexible substrates, or other types of substrates which will not be described herein. The second substrate 20 is disposed corresponding to the first substrate 10. A liquid crystal layer 18 is disposed between the second substrate 20 and the first substrate 10. The first substrate 10 further comprises a thin film transistor 50. The thin film transistor 50 comprises a gate 11a, an active layer 14, a source 12a, and a drain 12b. A first insulating layer 13 is disposed between the active layer 14 and the gate 11a, and the source 12a and the drain 12b are respectively connected to the active layer 14 by a through hole defined in a second insulating layer 15. The thin film transistor 50 is disposed at an intersection of the data line 12 and the gate line 11 and is located inside the grid 30. The gate 11a is electrically connected to the scan line 11. The source 12a is electrically connected to the data line 12. The source 12a and the drain 12b are arranged in a same layer as the data lines 12. The gate 11a is arranged in a same layer as the scan lines 11.

In some embodiments, please refer to FIGS. 2 and 3, the process markings 40 are arranged in a same layer as the data lines 12, or the process markings 40 are arranged in a same layer as the scan lines 11. A material of the data lines 12 or the scan lines 11 can be a metal material such as copper, aluminum, nickel, alloy thereof, or a mixture thereof. The process markings 40 can comprise a plurality of letters and/or numbers.

According to one embodiment of the present invention, the process markings 40 and the scanning lines 11 are arranged in a same layer as an example. In a manufacturing process of the thin film transistor 50, a gate metal layer is first deposited on the first substrate 10, and the gate metal layer is patterned to form the scan line 11, the gate 11a, and a metal marking block. The metal marking block is etched by a laser coding process to form the process marking 40. The process marking 40 comprises a first pattern 401 and a second pattern 402 surrounding a periphery of the first pattern 401. The first pattern 401 and the second pattern 402 are made of a same material as a material of the scan lines 11. The first pattern 401 is letters and/or numbers with an identification meaning, and the letters and/or the numbers are obtained by laser coding. When an etching depth of the laser coding process is equal to a thickness of the metal marking block, a hollow first pattern 401 is obtained. The above manufacturing process is a process understood by those skilled in the art, so a detailed description is omitted for brevity.

By arranging the process markings 40 in the same layer as the scan lines 11, a coating step on a metal material of the process markings 40 can be skipped. Moreover, the process markings 40 are made of metal. Therefore, when a detection device such as a charge coupled device (CCD) is used for identification, the metal reflects light to facilitate identification of the process markings 40.

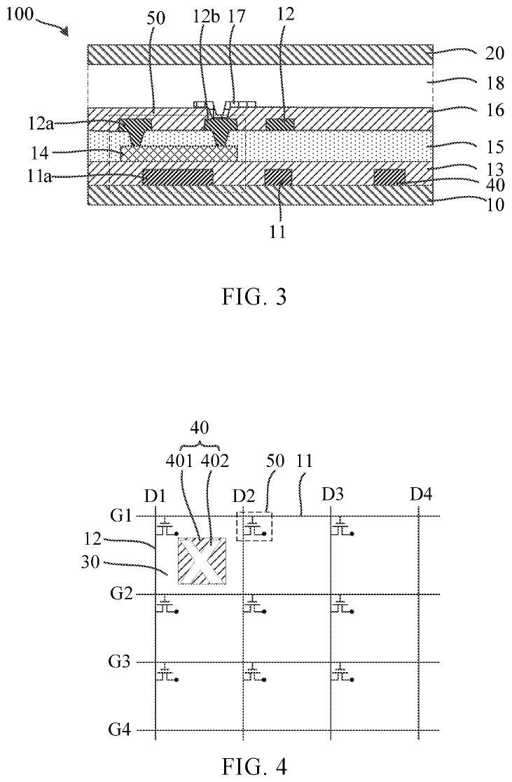

Moreover, as shown in FIG. 4, the second pattern 402 comprises a plurality of gaps spaced apart from each other. Without affecting recognition of the process markings 40, gaps can be arranged as many as possible in the second pattern 402 to reduce influence of the process markings 40 on a display image of the display panel 100. By means of the gaps, display performance of the display panel 100 is ensured, and a size of the process marking 40 can be enlarged to facilitate recognition of the process markings 40. It should be noted that a shape and a size of the gap are not specifically limited in the present invention.

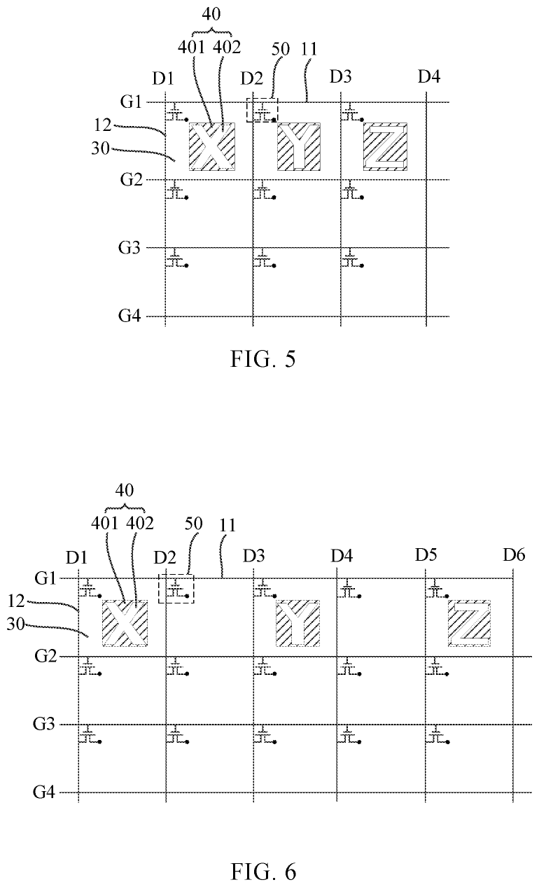

According to one embodiment of the present application, the process markings 40 comprise a plurality of numbers and/or letters. Please refer to FIG. 5, the process markings 40 of the present embodiment comprise the letters “X”, “Y”, and “Z” as an example. Projections of the letters “X”, “Y”, and “Z” on the first substrate 10 are respectively located within projections of the adjacent grids 30 on the first substrate 10. Since the letters “X”, “Y”, and “Z” are respectively arranged in different grids 30, a space for arranging the process markings 40 is increased. Thus, a size of the process marking 40 can be increased to facilitate recognition of the process markings 40 and meet the requirements for the laser coding process.

Moreover, adjacent numbers and/or letters are separated by at least one grid 30. Referring to FIG. 6, the process markings 40 of the present embodiment comprise the letters “X”, “Y”, and “Z” as an example. The letters “X”, “Y”, and “Z” are respectively arranged in different grids 30, and adjacent letters are separated apart by one grid 30. When the process markings 40 comprise multiple numbers and/or letters, this technical solution can increase a distance between the numbers and/or the letters to reduce the influence of the process markings 40 on the display performance of the display panel 100. The specific distance between the numbers and/or the letters can vary according to the size of the display panel 100 and display requirements.

It should be noted that the projections of the process markings 40 on the first substrate 10 are non-overlapped with projections of the gate 11a, the source 12 a, and the drain 12b on the first substrate 10 to avoid electrical problems between the process markings 40 and pixel circuits in the display panel 100, thus ensuring normal operations of the pixel circuits.

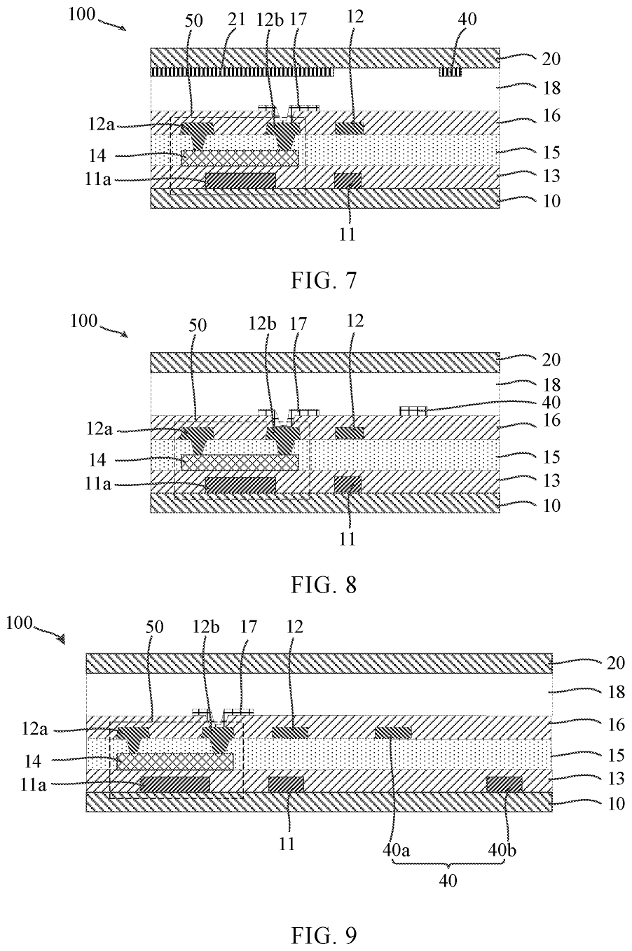

Please refer to FIG. 7, in some embodiments, the second substrate 20 comprises a black matrix 21. The black matrix 21 is disposed on one side of the second substrate 20 adjacent to the first substrate 10. A projection of the black matrix 21 on the first substrate 10 overlaps a projection of the thin film transistor 50 on the first substrate 10, so that metal film layers in the thin film transistor 50 reflect less ambient light and the display performance of the display panel 100 is improved. The process markings 40 are arranged in a same layer as the black matrix 21. The process markings 40 are made of a same material as a material of the black matrix 40, and the material is a light-shielding material such as ink.

According to one embodiment of the present invention, the process markings 40 are arranged in the same layer as the black matrix 21 and is made of the same light-shielding material as the black matrix 21. Since the light-shielding material can effectively absorb light, the process markings 40 can be clearly identified by a detection device such as a CCD through the first substrate 10.

It should be noted that the process markings 40 may be arranged in a same layer as other functional film layer of the display panel 100. For example, as shown in FIG. 8, the first substrate 10 further comprises a pixel electrode 17. The pixel electrode 17 is electrically connected to the drain 12b through a via hole defined in a planarization layer 16. The process markings 40 can be arranged in a same layer as the pixel electrode 17.

In some embodiments, as shown in FIG. 9, the process markings 40 comprise a first process marking 40a and a second process marking 40b. The first process marking 40a is arranged in a same layer as the data lines 12. The second process marking 40b is arranged in a same layer as the scan lines 11. A projection of the first process marking 40a projected on the first substrate 10 is non-overlapped with a projection of the second process marking 40b projected on the first substrate 10. The first process marking 40a is made of a same material as a material of the data lines 12, and the second process marking 40b is made of a same material as a material of the scan lines 11.

In the present invention, the process markings 40 are arranged on the inner surface of the first substrate 10, and the projections of the process markings 40 on the first substrate 10 are located within the projections of the grids 30, formed by the scanning lines 11 and the data lines 12 inserted with each other, on the first substrate 10. The present invention avoids arrangement of the process markings 40 in the bezel area of the display panel 100 with an ultra-narrow bezel, thereby avoiding a technical problem that the process markings 40 are difficult to identify, and facilitating recognition of the process markings 40. Further, the size of the process markings 40 can be increased by a hollow design of the second pattern 402 of the process marking 40 or by respectively arranging the numbers and/or the letters included in the process markings 40 in different grids 30. Thus, it is easier to identify the process markings 40, and at the same time, the influence of process markings 40 on the display performance of the display panel 100 is reduced.

The present invention further provides a display device. The display device includes the display panel described above. The display device may be a smart phone, a tablet computer, a video player, a personal computer (PC), and the like, and the present invention is not limited in this regard.

It should be noted that the cross-sectional structural view of the display panel of the present invention is only for a better understanding of positions and configurations of the process markings in the present invention, and cannot be understood as a limitation on the present invention. For example, the thin film transistor in the display panel of the present invention is a bottom-gate type, but the thin film transistor can also be a top-gate type; the pixel circuit in the display panel is composed of a single thin film transistor, but the pixel circuit can also be composed of multiple thin film transistors; and the display panel can further include other functional film layers such as a buffer layer or a color resist layer. The present invention does not specifically limit the above contents.

The embodiments of the present invention have been described in detail above to illustrate the working principles of the present invention. The above description is only provided for ease of understanding of the present invention and its main ideas. Those skilled in the art will be able to modify the embodiments and their applications. All such changes/modifications should be deemed to be within the protection scope of the present application. In conclusion, the content of the present disclosure should not be construed as limiting the present invention.

What is claimed is:

1. A display panel, comprising:
a first substrate comprising a plurality of scan lines and a plurality of data lines, wherein the scan lines and the data lines are intersected with each other to form a plurality of grids;
a second substrate disposed corresponding to the first substrate; and
a plurality of process markings arranged on an inner surface of the first substrate, wherein projections of the process markings projected on the first substrate are located within projections of the grids projected on the first substrate.

2. The display panel according to claim 1, wherein the process markings are arranged in a same layer as the scan lines or the data lines.

3. The display panel according to claim 2, wherein the process markings comprise a plurality of numbers and/or letters, and the adjacent numbers and/or letters are separated by at least one of the grids.

4. The display panel according to claim 1, wherein the process marking comprises a first pattern and a second pattern surrounding a periphery of the first pattern; and the first pattern and the second pattern are made of a same material as a material of the scan lines or the data lines.

5. The display panel according to claim 4, wherein the second pattern comprises a plurality of gaps spaced apart from each other.

6. The display panel according to claim 1, wherein the process markings comprise a first process marking and a second process marking, the first process marking is arranged in a same layer as the data lines, the second process marking is arranged in a same layer as the scan lines, and a projection of the first process marking projected on the first substrate is non-overlapped with a projection of the second process marking projected on the first substrate.

7. The display panel according to claim 6, wherein the first process marking is made of a same material as a material of the data lines, and the second process marking is made of a same material as a material of the scan lines.

8. The display panel according to claim 1, wherein the first substrate further comprises a thin film transistor, the thin film transistor comprises a gate, a source, and a drain; and
the projection of the process markings projected on the first substrate are non-overlapped with projections of the gate, the source, and the drain projected on the first substrate.

9. The display panel according to claim 1, wherein the first substrate further comprises a pixel electrode, and the process markings are arranged in a same layer as the pixel electrode.

10. The display panel according to claim 1, wherein the second substrate further comprises a black matrix, and the process markings are arranged in a same layer as the black matrix.

11. A display device, the display device comprising a display panel, the display panel comprising:
a first substrate comprising a plurality of scan lines and a plurality of data lines, wherein the scan lines and the data lines are intersected with each other to form a plurality of grids;
a second substrate disposed corresponding to the first substrate; and
a plurality of process markings arranged on an inner surface of the first substrate, wherein projections of the process markings projected on the first substrate are located within projections of the grids projected on the first substrate.

12. The display device according to claim 11, wherein the process markings are arranged in a same layer as the scan lines or the data lines.

13. The display device according to claim 12, wherein the process markings comprise a plurality of numbers and/or letters, and the adjacent numbers and/or letters are separated by at least one of the grids.

14. The display device according to claim 11, wherein the process markings comprise a first pattern and a second pattern surrounding a periphery of the first pattern; and the first pattern and the second pattern are made of a same material as a material of the scan lines or the data lines.

15. The display device according to claim 14, wherein the second pattern comprises a plurality of gaps spaced apart from each other.

16. The display device according to claim 11, wherein the process marking comprises a first process marking and a second process marking, the first process marking is arranged in a same layer as the data lines, the second process marking is arranged in a same layer as the scan lines, and a projection of the first process marking projected on the first substrate is non-overlapped with a projection of the second process marking projected on the first substrate.

17. The display device according to claim 16, wherein the first process marking is made of a same material as a material of the data lines, and the second process marking is made of a same material as a material of the scan lines.

18. The display device according to claim 11, wherein the first substrate further comprises a thin film transistor, the thin film transistor comprises a gate, a source, and a drain; and
the projection of the process markings projected on the first substrate are non-overlapped with projections of the gate, the source, and the drain projected on the first substrate.

19. The display device according to claim 11, wherein the first substrate further comprises a pixel electrode, and the process markings are arranged in a same layer as the pixel electrode.

20. The display device according to claim 11, wherein the second substrate further comprises a black matrix, and the process markings are arranged in a same layer as the black matrix.
